(19) United States
(12) Patent Application Publication
(10) Pub. No.: US 2016/0347643 A1
(43) Pub. Date: Dec. 1, 2016

(54) GLASS SUBSTRATE MANUFACTURING METHOD

(71) Applicant: Asahi Glass Company, Limited, Chiyoda-ku (JP)

(72) Inventors: Hiroyuki YAMAUCHI, Toyonaka-shi (JP); Go Takahashi, Toyonaka-shi (JP); Motoshi Ono, Chiyoda-ku (JP); Mamoru Isobe, Chiyoda-ku (JP)

(73) Assignee: Asahi Glass Company, Limited, Chiyoda-ku (JP)

(21) Appl. No.: 15/162,040

(22) Filed: May 23, 2016

(30) Foreign Application Priority Data
May 29, 2015 (JP) 2015-109277

(51) Int. Cl. C03B 33/09; H01L 21/48; C03C 15/00

(52) U.S. Cl. CPC C03B 33/091; C03C 15/00; H01L 21/486

(57) ABSTRACT

There is provided a glass substrate manufacturing method for manufacturing a glass substrate with a plurality of through-holes. The method includes a laser processing of forming the plurality of through-holes in the glass substrate, the glass substrate having a first main surface and a second main surface facing the first main surface, by irradiating a laser beam toward the first main surface; and an etching process of injecting an etchant only from a position facing the second main surface of the glass substrate toward the plurality of through-holes formed in the glass substrate.

### CROSS-REFERENCE TO RELATED APPLICATION

The present application is based on and claims the benefit of priority of Japanese Priority Application No. 2015-109277 filed on May 29, 2015, the entire contents of which are hereby incorporated by reference.

### BACKGROUND OF THE INVENTION

1. Field of the Invention

The present invention relates to a glass substrate manufacturing method for forming a through-hole in a glass substrate, and especially relates to a glass substrate manufacturing method with which a through-hole can be accurately foamed by spray etching.

2. Description of the Related Art

Recently, a glass substrate in which a plurality of through-holes are formed has been broadly used for electronic devices. As an example of applying a glass substrate having micro through-holes, there is a three-dimensional integrated circuit using an interposer. For an interposer, a resin substrate has been used so far. However, due to a difference between a thermal expansion coefficient of the resin substrate and a thermal expansion coefficient of an IC chip, a failure may occur in a bonding portion. Thus, a silicon substrate and a glass substrate have been focused on, and failures due to the difference between the thermal expansion coefficients are reduced for both silicon substrates and glass substrates. However, the silicon substrate has a disadvantage of high cost. Thus, a glass substrate has been greatly focused on due to low cost, and a superior electrical insulation property.

The interposer is connected to a circuit on a bottom surface by a structure including a plurality of through-holes formed in the substrate. Thus, it is necessary to form through-holes in a glass substrate. A plurality of through-holes can be formed in a glass substrate by using laser processing. In this case, however, edge faces of the formed through-holes include micro cracks. Thus, the glass substrate is immersed in an etchant. In this manner, a glass substrate for an interposer can be produced, which includes the through-holes such that the edge faces of the through holes are smooth (cf. Patent Document 1, for example).

### PATENT DOCUMENT

[Patent Document 1] Japanese Unexamined Patent Publication No. 2003-226551

### SUMMARY OF THE INVENTION

According to an etching method where a glass substrate is immersed in an etchant, such as the method according to Patent Document 1, the etchant may not reach inside the fine through-holes, so that individual through-holes may be unevenly formed. Usually, a through-hole formed by laser processing has a tapered shape, and there is a difference between a diameter of the hole on a front main surface and a diameter of the hole on a rear main surface, even after an etching process (cf. Patent Document 1, for example). If there is a difference between the diameter of the hole on the front main surface and the diameter of the hole on the rear main surface, the difference may adversely affect the use of the glass substrate. For example, if a through-electrode is formed inside a through-hole by using such glass as an interposer, a resistance value of the through-hole may be large. Furthermore, for a case of using plating to form a through-electrode, growth of plating may become uneven, and a flow of a plating solution may be blocked. Consequently, uniform plating may not be formed.

An object of an embodiment of the present invention is to provide a method of manufacturing a glass substrate in which through-holes can be easily formed by laser processing and etching such that, for each of the through-holes, a difference between a diameter of the hole on a front main surface and a diameter of the hole on a rear main surface is small.

According to an aspect of the present invention, there is provided a glass substrate manufacturing method for manufacturing a glass substrate with a plurality of through-holes. The glass substrate manufacturing method includes a laser processing of forming the plurality of through-holes in the glass substrate, the glass substrate having a first main surface and a second main surface facing the first main surface, by irradiating a laser beam toward the first main surface; and an etching process of injecting an etchant from, at least, a position facing the second main surface of the glass substrate toward the plurality of through-holes formed in the glass substrate.

In the etching process of the glass substrate manufacturing method, the glass substrate may be disposed so that the second main surface is at an upper side.

According to another aspect of the present invention, there is provided a glass substrate manufacturing method for manufacturing a glass substrate with a plurality of through-holes. The method includes a laser processing of forming the plurality of through-holes in the glass substrate, the glass substrate having a first main surface and a second main surface facing the first main surface, by irradiating a laser beam toward the first main surface; and an etching process of injecting an etchant from a first position facing the first main surface of the glass substrate and a second position facing the second main surface of the glass substrate toward the plurality of through-holes formed in the glass substrate.

According to an embodiment of the present invention, through-holes can be easily formed by laser processing and etching such that, for each of the through-holes, a difference between a diameter of the hole on a front main surface and a diameter of the hole on a rear main surface is small.

### BRIEF DESCRIPTION OF THE DRAWINGS

Other objects, features and advantages of the present invention will become more apparent from the following detailed description when read in conjunction with the accompanying drawings.

FIGS. 1A and 1B are diagrams illustrating examples of a state where a laser processing is executed;

FIGS. 2A and 2B are diagrams illustrating examples of a state where an etching process is executed;

FIG. 3A is a diagram illustrating the etching process according to an embodiment of the present invention;

FIG. 3B is a diagram illustrating a cross section of through-holes obtained by the etching process according to the embodiment;

FIG. 4A is a diagram illustrating an etching process according to a reference example; and

FIG. 4B is a diagram illustrating a cross section of through-holes obtained by the etching process according to the reference example.

### DETAILED DESCRIPTION OF THE PREFERRED EMBODIMENTS

According to an embodiment of the present invention, there is provided a glass substrate manufacturing method for manufacturing a glass substrate with a plurality of through-holes. The glass substrate manufacturing method includes a laser processing of forming the plurality of through-holes in the glass substrate, the glass substrate having a first main surface and a second main surface facing the first main surface, by irradiating a laser beam toward the first main surface; and an etching process of injecting an etchant from, at least, a position facing the second main surface of the glass substrate toward the plurality of through-holes formed in the glass substrate.

According to the embodiment of the present invention, the plurality of through-holes are formed in the glass substrate by irradiation of the laser beam. However, micro cracks are included in edge faces of the through-holes, so that strength of the glass substrate may be lowered. The strength of the glass substrate can be maintained by micronizing or eliminating the micro cracks by etching the micro cracks by spraying. Moreover, by executing etching by spraying, an etchant can penetrate into each of the plurality of through-holes, so that uniform etching can be achieved.

According to the embodiment of the present invention, in the etching process, the etchant is injected from, at least, a position facing the second main surface toward the through-holes formed in the glass substrate. As for diameters of openings of the through-hole formed by irradiation of a laser beam, the diameter of the opening of the through-hole formed on the second main surface, which corresponds to an exit of the laser beam, is less than the diameter of the opening of the through-hole formed on the first main surface, so that, by intensively etching the through-holes on the second main surface, for each of the through-holes, a difference between the diameter of the opening on the first main surface and the diameter of the opening on the second main surface can be reduced.

Additionally, in the etching process, the glass substrate may preferably be disposed so that the second main surface is at an upper side. Note that the substrate may preferably disposed so that the substrate is approximately parallel to a horizontal plane (preferably in a range from ±2 degrees from the horizontal plane). As for diameters of openings of the through-holes formed by irradiation of a laser beam, the diameter of the opening of the through-hole formed on the second main surface, which corresponds to an exit of the laser beam, is less than the diameter of the opening of the through-hole formed on the first main surface.

Comparing an amount of etching for a case of injecting the etchant onto the upper surface of the glass substrate with an amount of etching for a case of injecting the etchant onto the lower surface of the glass substrate, the etchant tends to stay longer for the case of injecting the etchant onto the upper surface of the glass substrate, so that the amount of etching is greater for the case of injecting the etchant onto the upper surface of the glass substrate, corresponding to an increased amount of time in which the etchant contacts the glass substrate. Thus, by etching while placing the second main surface at an upper side, the through-holes on the second main surface can be more intensively etched, compared to the through-holes on the first main surface. As a consequence, in the etching process, a difference between the diameter of the opening on the first main surface and the diameter of the opening on the second main surface can be reduced.

Additionally, the time for etching may preferably be adjusted, so that the difference between the diameter of the opening on the first main surface and the diameter of the opening on the second main surface can be cancelled. Then, the through-hole can be formed to have an approximately columnar shape with less taper, which is suitable for forming a through-electrode, as an interposer, for example. For example, the time for injecting the etchant toward the second main surface of the glass substrate may be adjusted to be longer than the time for injecting the etchant toward the first main surface. At this time, the glass substrate may be disposed so that the second main surface is at the upper side.

Additionally or alternatively, the injection pressure for injecting the etchant toward the second main surface may be adjusted to be higher than the injection pressure for injecting the etchant toward the first main surface. By adjusting the injection pressure, the difference between the diameter of the opening on the first main surface and the diameter of the opening on the second main surface can be reduced. At this time, the glass substrate may be disposed, so that the second main surface is at the upper side. Additionally, when the second main surface is at the upper side and there is a difference in the injection pressure, the injection pressure may preferably be adjusted so that the pressure of the etchant injected toward the second main surface can be from 1.1 times to 1.2 times higher than the pressure of the etchant injected toward the first main surface. Then, the difference between the diameter of the opening on the first main surface and the diameter of the opening on the second main surface can be significantly reduced. If the injection pressure is within the above-described range, the difference between the diameter of the opening on the first main surface and the diameter of the opening on the second main surface can be easily reduced. Thus, it is preferable that the injection pressure be within the above-described range. Furthermore, if the injection pressure is within the above-described range, the diameter of the opening on the second main surface may not be unnecessary widened. Thus, it is preferable that the injection pressure be within the above-described range.

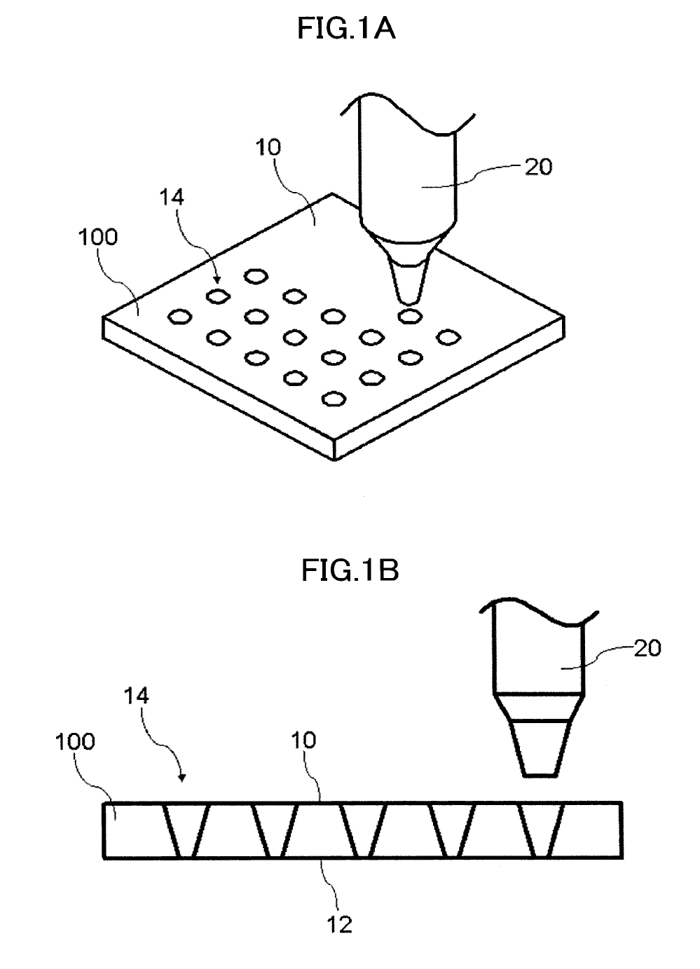

The glass substrate manufacturing method according to the embodiment of the invention is described below by referring to the drawings. As illustrated in FIG. 1A and FIG. 1B, through-holes 14 are formed in the glass substrate 100 by laser processing. The glass substrate 100 includes the first main surface 10 and the second main surface 12. The laser beam is to be irradiated onto the first main surface 10. The second main surface 12 is opposite to the first main surface 10. The type of the glass substrate 100 is not particularly limited, as long as it is glass. However, if the glass substrate 100 is to be used for a package of a semiconductor element, such as a glass interposer, non-alkaline glass may be preferable. The reason is that, if alkali-containing glass is used, an alkali component in the glass may be eluted, and the eluted alkali component may adversely affect the semiconductor element. Further, the thickness of the glass substrate 100 is not particularly limited. The thickness of the glass substrate 100 may be from 0.05 mm to 0.7 mm, for example.

To form fine through-holes 14 in the glass substrate 100, a laser 20 is used. In the embodiment, a CO₂ laser 20 is used. However, the laser 20 is not limited to the CO₂ laser. Another laser 20, such as a YAG laser, a YVO₄ laser, and an excimer laser, may be properly selected by totally considering a beam diameter, processing precision, power, and so forth. A laser beam from the laser 20 is irradiated onto the first main surface 10 of the glass substrate 100. A diameter of a focal spot of the laser beam on the first main surface of the glass substrate 100 is in a range from 10 μm to 200 μm, for example. As a result, the temperature of the irradiated position of the glass substrate 100 is locally increased, and the glass sublimates, thereby forming the through-hole 14.

A plurality of through-holes 14 is formed in the glass substrate 100 by the laser 20. As illustrated in FIG. 1B, comparing the diameter of the through-hole 14 on the first main surface 10, from which the laser beam enters, with the diameter of the through-hole 14 on the second main surface 12, which is opposite to the first main surface 10, the diameter of the hole on the first main surface 10 is greater than the diameter of the hole on the second main surface 12, so that the taper shaped through-hole 14 is formed. In the through-hole 14 formed by the laser 20, there are micro cracks in the edge surface inside the through-hole, so that the strength of the glass substrate 100 may be lowered. The strength of the glass substrate 100 can be enhanced by micronizing or eliminating the micro cracks by the subsequent etching process. Furthermore, the diameter of the through-hole 14 can be increased in the subsequent etching process, and thereby a through-hole with a diameter can be obtained, which may not be achieved only by adjusting the condition of laser irradiation.

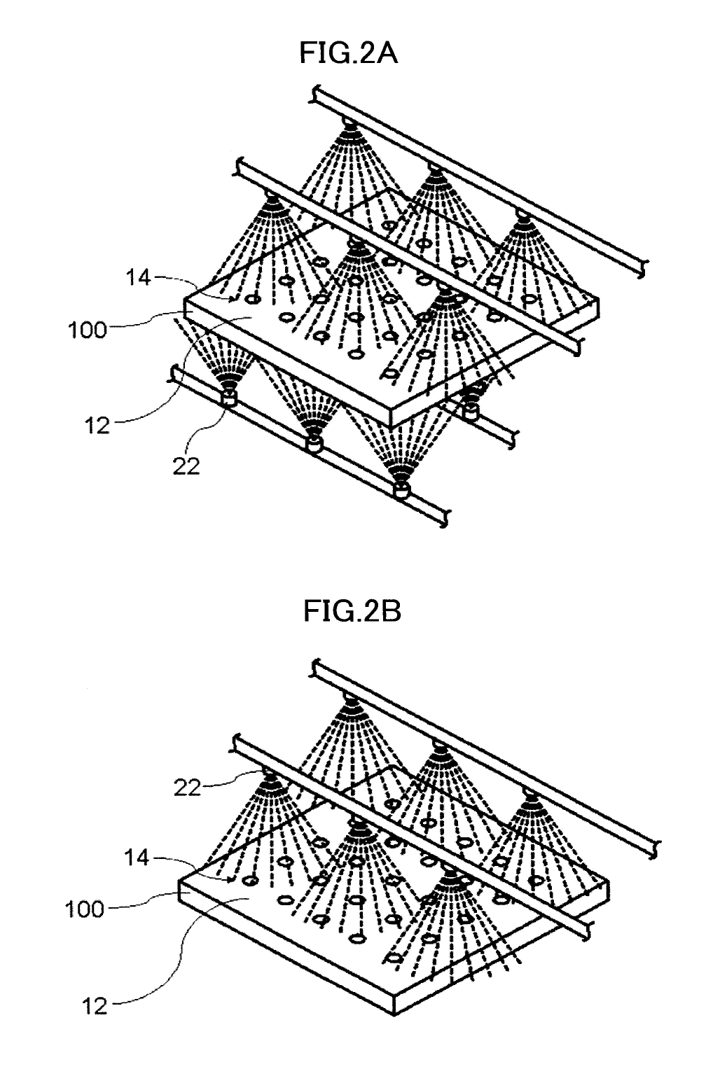

After the plurality of fine through holes 14 are formed by the laser 20, the glass substrate 100 is etched by the etchant, as illustrated in FIG. 2A and FIG. 2B. In FIG. 2A and FIG. 2B, depiction of conveyance rollers, which are for conveying the glass substrate 100 while supporting the glass substrate 100 from below, is omitted for convenience of illustration. The etchant is injected from spray nozzles 22, which are disposed above and below the glass substrate 100, or only disposed above the glass substrate 100. The spray nozzles 22 disposed above and below inject under the same conditions. As a composition of the etchant, there are a hydrofluoric acid; a mixture of a hydrofluoric acid and another acid; KOH; and so forth.

In the embodiment, the glass substrate 100 may preferably be etched while the second main surface 12 is arranged at the upper side. The etchant tends to stay at the upper side of the glass substrate 100, so that the amount of etching at the upper side is greater than the amount of etching at the lower side. In the plurality of through-holes 14 formed by the laser 20, there are micro cracks in the edge surfaces inside the through-holes 14, so that the strength of the glass substrate 100 is lowered. The strength of the glass substrate 100 can be maintained by micronizing or eliminating the micro cracks in the edge surfaces inside the through-holes 14 by etching.

Usually, the micro cracks can be micronized or eliminated by immersing the glass substrate 100 in the etchant. However, if there are fine through-holes 14, the etchant may not reach the individual fine through-holes 14, so that the glass substrate 100 may not be uniformly etched. As a result, some micro cracks may not be etched, and these micro cracks may remain. Moreover, the through-holes 14 may be formed such that the diameters of the through-holes 14 are not uniform. In the embodiment of the present invention, the etchant can be made to penetrate into the individual fine through-holes 14 by injecting the etchant toward the formed through-holes 14 from above and below the glass substrate 100 by using the spray nozzles 22. Even by etching only from above, the etchant can be made to penetrate into the through-holes 14 by the pressure by the spray nozzles 22, so that the micro cracks inside the through-holes 14 can be micronized or eliminated.

Further, for a case of the etching method by immersing the glass substrate 100 in the etchant, the glass substrate 100 is processed according to a batch method or a single wafer method by immersing the glass substrate 100 in the etchant. In contrast, with the method of injecting the etchant, the glass substrate 100 can be continuously etched while the glass substrate 100 is supported by the conveyance rollers, for example. Thus, mass productivity can be enhanced.

Furthermore, with the method of injecting the etchant, an amount of etching on the first main surface and an amount of etching on the second main surface can be individually and easily controlled, compared to the method by immersing the glass substrate 100 in the etchant. Consequently, the diameter of the through-holes 14 on the first main surface and the diameter of the through-holes 14 on the second main surface can be individually and easily adjusted. For example, as illustrated in FIG. 2A, the spray nozzles 22 can be disposed above and below the glass substrate 100. In this case, by individually controlling the condition of injection from the spray nozzles 22 (injection pressure of the etchant or a time of injection) at the upper side and at the lower side, one of the main surfaces of the glass substrate 100 can be intensively etched, or an amount of etching on one of the main surfaces of the glass substrate 100 can be reduced.

Furthermore, in order to enhance uniformity, the glass substrate 100 may be etched while the spray nozzles 22 are fluctuated. The pressure for injecting the etchant from the spray nozzles 22 may preferably be from 0.05 Mpa to 0.10 Mpa. In addition, a favorable result can be obtained, if the glass substrate 100 is processed while adjusting the amount of the etchant to be injected from each spray nozzle 22 to be approximately from 1.25 to 2.50 l/min, and adjusting the total number of the nozzles 22 to be approximately from 120 to 180. Furthermore, by increasing the pressure for injecting the etchant from the spray nozzles 22 at the upper side approximately from 10 to 20%, the difference between the diameter of the through-hole 14 at the upper surface and the diameter of the through-hole 14 at the lower surface tends to be reduced. Thus, depending on necessity, the pressure for injecting the etchant from the spray nozzles 22 at the upper side may preferably be increased.

Furthermore, by adjusting the pressure for injecting the etchant from the spray nozzles 22 facing the second main surface 12 to be higher than the pressure for injecting the etchant from the spray nozzles 22 facing the first main surface 10 by approximately 10% to 20%, the difference between the diameter of the through-hole 14 at the first main surface 10 and the diameter of the through-hole 14 at the second main surface 12 tends to be reduced. Thus, depending on necessity, the pressure for injecting the etchant from the spray nozzles 22 facing the second main surface 12 may preferably be adjusted to be greater than the pressure for injecting the etchant from the spray nozzles 22 facing the first main surface 10.

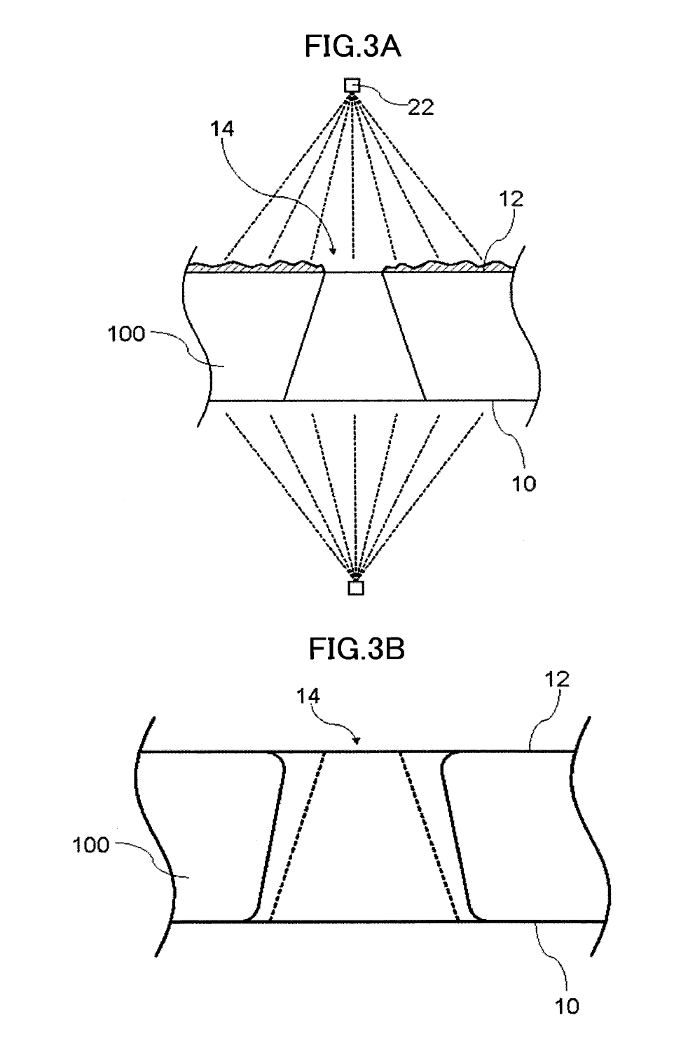

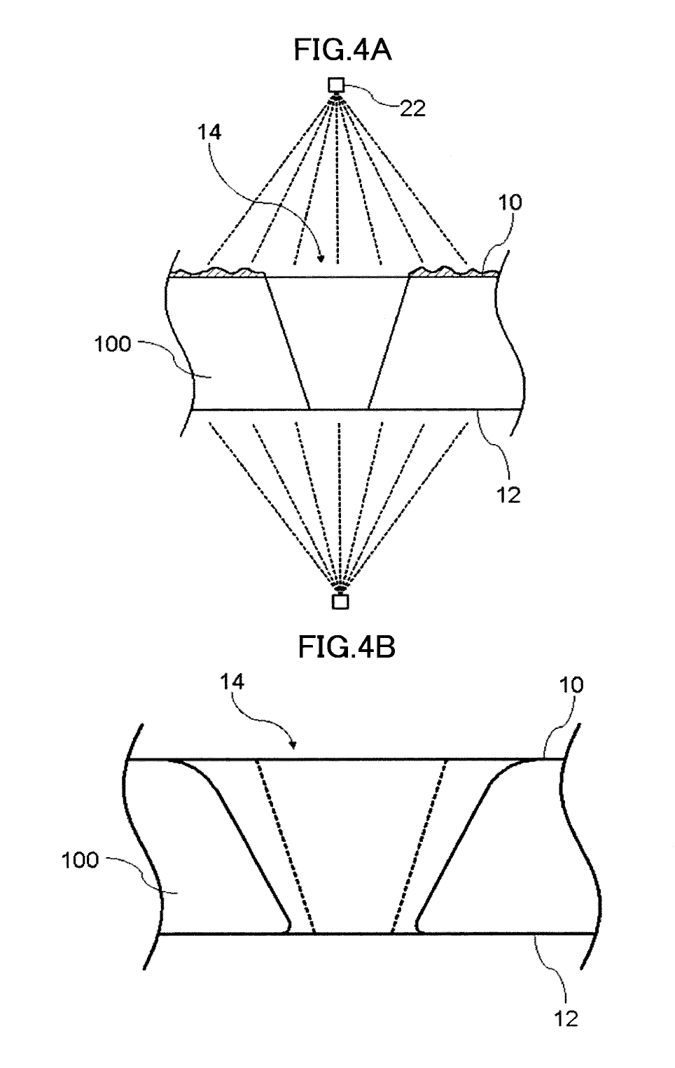

FIG. 3A and FIG. 4A are diagrams illustrating partial cross-sections of the glass substrate 100 where the etchant is injected, from above and below the glass substrate 100, onto the through hole 14 formed in the glass substrate 100. FIG. 3B and FIG. 4B are diagrams illustrating partial cross-sections of the glass substrate 100 after the etching process. FIG. 3A illustrates a state of the through-hole 14 of the glass substrate 100 during etching while arranging the second main surface 12, on which the diameter of the through-hole 14 is small, to be the upper surface. A part of the etchant injected by the spray nozzle 22 disposed at the upper side penetrates into the through-hole 14, and another part of the etchant injected by the spray nozzle 22 disposed at the upper side stays on the upper surface of the glass substrate 100. A part of the etchant injected by the spray nozzle 22 disposed at the lower side penetrates into the through-hole 14, and another part of the etchant injected by the spray nozzle 22 disposed at the lower side is blocked by the lower surface of the glass substrate 100, and the other part of the etchant flows downward without staying. In FIG. 3A and FIG. 4A, the states are depicted where the etchant is injected from above and below the glass substrate 100. However, as illustrated in FIG. 2B, the etchant may be injected only from above the glass substrate 100.

Comparing an amount of etching on the upper surface of the glass substrate 100 with an amount of etching on the lower surface of the glass substrate 100, the amount of etching is greater on the upper surface of the glass substrate 100, corresponding to the amount of the etchant staying on the upper surface. In contrast, on the lower surface of the glass substrate 100, almost no etchant stays on the lower surface, and almost all etchant flows downward. Thus, the amount of etching on the lower surface is small compared to the amount of etching on the upper surface.

FIG. 3B is a diagram illustrating a partial cross section of the glass substrate 100 for a case where etching is executed while arranging the second main surface 12, on which the diameter of the through-hole 14 formed in the glass substrate 100 is small, to be the upper side. Compared to the lower surface, the amount of etching on the upper surface is greater, so that the shape of the through-hole 14, which has been formed to have the tapered shape, becomes a shape that is close to a columnar shape. Furthermore, if the etchant is injected only from above the glass substrate 100, the amount of etching on the lower surface can be reduced, so that finer through-holes 14 can be formed.

FIG. 4A illustrates a state of the through-hole 14 of the glass substrate 100 during etching while the surface, on which the diameter of the through-hole 14 is large, is arranged at the upper side. Similar to the case of FIG. 3A, an amount of etching is great on the upper surface, corresponding to the amount of the etchant staying on the upper surface. An amount of etching on the lower surface is small compared to the upper surface because almost no etchant stays on the lower surface, and the etchant flows downward.

FIG. 4B is a diagram illustrating a partial cross section of the glass substrate 100 that is etched while arranging the first main surface 10, on which the diameter of the through-hole 14 formed in the glass substrate 100 is large, at the upper side. Since the amount of etching is greater on the upper surface compared to the lower surface, in the through-hole 14, which has been formed to have the tapered shape, the difference between the diameter of the through-hole 14 on the upper surface and the diameter of the through-hole 14 on the lower surface is increased. Furthermore, for a case where the etchant is injected only from above the glass substrate 100, etching on the lower surface tends not to be progressed, so that the difference between the diameter of the through-hole 14 on the upper surface and the diameter of the through-hole 14 on the lower surface is further increased.

Considering a method of forming a through electrode, and a resistance value, such as electrode, a columnar shape is suitable for the shape of the through-hole 14 of the interposer. For etching the through-hole 14 that is formed in the glass substrate 100, by comparing the case where the first main surface 10 is arranged at the upper side with the case where the second main surface 12 is arranged at the upper side, it can be seen that the through-hole 14 having a shape close to the columnar shape can be obtained by arranging the second main surface 12 at the upper side. Additionally, the through-hole 14 can be formed in a small area, so that the plurality of through-holes 14 can be formed while reducing the distance between the adjacent through-holes 14. In the above-described embodiment, the example is described where the glass substrate 100 is used as the interposer. However, application of the glass substrate 100 is not limited to the interposer. For example, the glass substrate 100 may be applied for MEMS packaging, a microchip device for life science, and so forth.

The above-described embodiment is illustrative for all respects, and the present invention is not limited to the embodiment. The scope of the present invention is not indicated by the above-described embodiment, and the scope of the present invention is indicated by the claims. Furthermore, the scope of the present invention is intended to include all modifications within the scope of the claims and meaning and the scope of equivalents.

### EXAMPLE

Next, an example of the embodiment of the present invention is described.

By using the laser processing illustrated in FIG. 1A and the etching process illustrated in FIG. 2A, 10000 through holes were formed on a glass substrate, and diameters of the obtained through-holes were examined. In the etching process, as illustrated in FIG. 3A, the glass substrate was disposed so that the second main surface, on which the diameter of the through-hole was small, was the upper surface. As the glass substrate, non-alkaline glass having thickness of 0.4 mm (EN-Al, produced by Asahi Glass Co. Ltd.) was used. As the laser, a CO₂ laser with a wavelength of 9.4 μm was used. The laser beam was irradiated to focus on the main surface of the glass substrate facing the laser by using a non-spherical lens having a focal length of 25 mm. The output power of the laser beam irradiated onto the glass substrate was set to 60 W. Additionally, the time for irradiating the laser beam was 360 μs. The glass substrate was moved with a pitch of 200 μm by using an XY stage, and hole drilling was executed at 100 rows and 100 columns, i.e., at 10000 positions in total.

Subsequently, the glass substrate, in which the through-holes were formed by laser processing, was etched by using the method according to FIG. 2A. Etching was performed while dividing the process into a first step to execute processing using sulfuric acid, and a second step to execute processing by diluting hydrofluoric acid with water. In the etching method, as illustrated in FIG. 2A, the etchant was injected onto the glass substrate, which was conveyed by the conveyance rollers, by using the spray nozzles that were disposed at a position separated from the glass substrate by 20 cm in the upward direction, and the spray nozzles that were disposed at a position separated from the glass substrate by 20 cm in the downward direction.

In the process of the first step, the etching process was performed for 3 minutes with an etchant formed of an aqueous solution including 75 wt % sulfuric acid, and 0.5 wt % hydrofluoric acid, under the conditions where the temperature of the etchant was 30° C.; the spray pressure was 0.07 Mpa (the calculated spray impact per unit area on the glass substrate was approximately 0.12 g/cm²); and the etching rate was 4 μm/min.

In the process of the second step, the etching process was performed for 6 minutes with an etchant formed of an aqueous solution including 25 wt % hydrochloric acid, and 3 wt % hydrofluoric acid, under the conditions where the temperature of the etchant was 40° C.; the spray pressure was 0.07 Mpa; and the etching rate was 3 μm/min. By the etching at the first step and the etching at the second step, a process of 9 minutes in total was performed to execute etching of 30 μm.

Here, the amount of etching is defined to be a value of a decrement amount of the thickness of the glass substrate. The etching rate is defined to be a value of a decrement amount of the thickness of the glass substrate per unit time (minute).

In the through-hole that was obtained after etching, the diameter of the through-hole on the first main surface was 90 μm, and the diameter of the through-hole on the second main surface was 65 μm. At this time, the difference between the diameter of the through-hole on the first main surface and the diameter of the through-hole on the second main surface was 25 μm.

### REFERENCE EXAMPLE

By using a method that was the same as the method of the above-described example, 10000 through holes were formed on a glass substrate, and shapes of the formed through-holes were examined. However, for the etching process of the reference example, the method illustrated in FIG. 4A was used. In the through-hole that was obtained after etching, the diameter of the through-hole on the first main surface was 93 μm, and the diameter of the through-hole on the second main surface was 58 μm. At this time, the difference between the diameter of the through-hole on the first main surface and the diameter of the through-hole on the second main surface was 35 μm. By the above-described result, it can be seen that, for the case of the example, the difference between the diameter of the through-hole on the first main surface and the diameter of the through-hole on the second main surface was reduced, compared to the case of the reference example. Namely, it can be said that, by the method described in the example, the through-hole which is formed to have a tapered shape can be reshaped to be a through-hole having a shape closer to the columnar shape. Thus, by using a processing method, such as the method of the above-described example, a through-hole can be easily formed such that a difference between a diameter of the through-hole on the first main surface and a diameter of the through-hole on the second main surface is small. Therefore, the method according to the embodiment is suitable as a method for forming a through-hole for an interposer.

What is claimed is:

1. A method of manufacturing a glass substrate with a plurality of through-holes, the method comprising:
laser processing of forming the plurality of through-holes in the glass substrate, the glass substrate having a first main surface and a second main surface facing the first main surface, by irradiating a laser beam toward the first main surface; and
an etching process of injecting an etchant only from a position facing the second main surface of the glass substrate toward the plurality of through-holes formed in the glass substrate.

2. A method of manufacturing a glass substrate with a plurality of through-holes, the method comprising:
laser processing of forming the plurality of through-holes in the glass substrate, the glass substrate having a first main surface and a second main surface facing the first main surface, by irradiating a laser beam toward the first main surface; and
an etching process of injecting an etchant from a first position facing the first main surface of the glass substrate and a second position facing the second main surface of the glass substrate toward the plurality of through-holes formed in the glass substrate.

3. The method of manufacturing according to claim 1,
wherein, in the etching process, the glass substrate is disposed, so that the second main surface is at an upper side.

4. The method of manufacturing according to claim 2,
wherein, in the etching process, second injection pressure to inject the etchant from the second position facing the second main surface is higher than first injection pressure to inject the etchant from the first position facing the first main surface.

5. The method of manufacturing according to claim 2,
wherein, in the etching process, a second time for injecting the etchant from the second position facing the second main surface is longer than a first time for injecting the etchant from the first position facing the first main surface.

6. The method of manufacturing according to claim 1,
wherein, in the etching process, the glass substrate is supported by one or more conveyance rollers.

7. The method of manufacturing according to claim 2,
wherein, in the etching process, the glass substrate is supported by one or more conveyance rollers.
